(19) United States
(12) Patent Application Publication
(10) Pub. No.: US 2026/0092351 A1
(43) Pub. Date: Apr. 2, 2026

(54) PROCESS FOR CREATING REFRACTORY CARBIDE PARTS BY CARBURIZING METAL

(71) Applicant: Wolfspeed, Inc., Durham, NC (US)

(72) Inventors: Brian HAIDET, Raleigh, NC (US); Caleb KENT, Durham, NC (US); Alexander SHVEYD, Chapel Hill, NC (US)

(21) Appl. No.: 18/963,136

(22) Filed: Nov. 27, 2024

Related U.S. Application Data
(60) Provisional application No. 63/700,682, filed on Sep. 28, 2024.

(51) Int. Cl. C23C 8/64; C01B 32/914; C09D 1/00; C30B 35/00

(52) U.S. Cl. CPC C23C 8/64; C01B 32/914; C09D 1/00; C30B 35/00

(57) ABSTRACT

The present disclosure relates generally to creating metal carbide parts or parts with metal carbide layers. In some aspects, the present disclosure relates to converting metal parts to metal carbide parts or parts with metal carbide layers. In other aspects, the present disclosure relates to metal-impregnated coatings that may be used to form metal carbide layers on parts. In yet other aspects, the present disclosure relates to metal-impregnated resins being used as material for 3D printing, casting, or coating disposable substrates, or otherwise forming objects that become standalone ceramic parts upon heat treatment and carburization of the metal.

### TECHNICAL FIELD

The present disclosure relates generally to creating metal carbide parts or parts with metal carbide layers. In some aspects, the present disclosure relates to converting metal parts to metal carbide parts or parts with metal carbide layers. In other aspects, the present disclosure relates to metal-impregnated coatings that may be used to form metal carbide layers on parts. In yet other aspects, the present disclosure relates to metal-impregnated resins being used as material for 3D printing, casting, or coating disposable substrates, or otherwise forming objects that become standalone ceramic parts upon heat treatment and carburization of the metal.

### BACKGROUND

Semiconductor devices, including power semiconductor devices based on wide bandgap materials, may be formed on a semiconductor wafer as part of a semiconductor fabrication process. Single crystal silicon carbide (SiC) has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

The graphite materials used in bulk crystal reactors and epitaxial growth reactors are subjected to a corrosive and high temperature environment. Reactive gaseous species used in such processes, like Si, Si₂C and SiC₂, chemically etch the graphite surfaces. The components used in the crucible are often limited to a single use, and costly larger parts inside the grower chamber break down with successive crystal growths. The deterioration of graphite has other detrimental consequences by introducing defects which impact the crystal quality. As the graphite of the crucible breaks down, microparticles are generated. When these fragments are incorporated into the growing crystal, they become a graphite inclusion defect which can lead to more pervasive crystal defects like dislocations and micropipes. Chemical etching can also have other unintended consequences because it alters the precise geometries of the graphite parts, impacting the sensitive thermal conditions needed to grow high-quality crystals.

To protect the graphite from degradation during SiC crystal growth, parts may be coated with tantalum carbide (TaC), a refractory ceramic that has exceptional hardness, high melting point, low chemical reactivity, and robust thermal stability at high temperatures.

### SUMMARY

There currently exist certain challenges in coating graphite and other materials with metal carbide. For example, one current approach used to coat graphite with TaC uses chemical vapor deposition (CVD) through the chlorination, oxidation, and then carbothermic reduction of tantalum metal. To grow a TaC coating on a graphite part, toxic halogen containing gasses are delivered to the reactor, and caustic side products must be disposed of post-processing. There are significant manufacturing costs associated with the infrastructure needed to handle these challenging materials. Tuning the layer thickness and scaling the process is also not trivial. The carbon source in the TaC coating, which originates from the graphite substrate, is diffusion-limited. Carbon atoms migrate through a growing layer of TaC to react with newly deposited Ta ions at the surface to keep growing the coating. This reaction mechanism produces an upper bound of about 35 μm on the final thickness that can be achieved and limits the growth rate of the coating. Yet another shortcoming of some approaches using a CVD process is that the impurity grade of TaC coated products may be influenced by the impurities of any part processed in the CVD reactor, effectively limiting the process to purified graphite only. There is also an upper bound on the size and quantity of parts that can be coated simultaneously with some CVD reactors. Another significant drawback of some approaches is a limitation to coating hard graphite only. Grower components not made from hard graphite therefore cannot be TaC coated using some approaches.

Certain aspects of the disclosure and their embodiments may provide solutions to these or other challenges.

In contrast to existing approaches, certain aspects of the disclosure and their embodiments may allow the creation of stronger multi-use parts than allowed with graphite parts, including parts that more resistant to etching than graphite. Certain aspects of the disclosure and their embodiments may also allow the creation of parts with finer machining features an allowing for part geometries that may not be possible with graphite parts.

Certain aspects of the disclosure and their embodiments describe a method for creating a component for use in a crystal growth system, including heating an article including at least a metal layer on at least one surface; providing a source of carbon wherein a metal carbide layer is formed on the at least one surface of the article.

Certain aspects of the disclosure and their embodiments describe a component, including a metal component having a metal carbide layer on at least one surface; wherein the metal carbide layer is formed by heating the metal article in a crucible with a source of carbon.

Certain aspects of the disclosure and their embodiments describe a method for creating an article for use in a crystal growth system, including providing an component having at least a metal layer on at least one surface; applying a coating to the at least one surface; wherein the coating includes metal particles and a binder; heating the coated article with a source of carbon; wherein a metal carbide layer is formed on the at least one surface of the article.

Certain aspects of the disclosure and their embodiments describe a component, including an article having a metal carbide layer on at least one surface; wherein the metal carbide layer is formed using a paint applied to the at least one surface and heating the article with the paint applied to the at least one surface in the presence of a source of carbon; wherein the paint includes metal particles and a binder.

Certain aspects of the disclosure and their embodiments describe a method for creating a component, including forming the component using a viscous material including metal particles and a binder; providing a source of carbon; and heating the part such that the part becomes solid metal carbide.

Certain aspects of the disclosure and their embodiments describe a component including a viscous material comprising metal particles and a binder that has been heated in the presence of a source of carbon such that the viscous material becomes solid metal carbide.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

The accompanying drawings, which are included to provide a further understanding of the disclosure and are incorporated in and constitute a part of this application, illustrate certain non-limiting embodiments of inventive concepts. In the drawings:

FIG. 1 depicts a crystal growth system that may utilize components according to example embodiments of the present disclosure;

FIG. 2 depicts a crystal growth system that may utilize components according to example embodiments of the present disclosure;

FIG. 3 depicts a crystal growth system that may utilize components according to example embodiments of the present disclosure;

FIG. 4 depicts a crystal growth system that may utilize components according to example embodiments of the present disclosure;

FIG. 5A depicts a perspective view of a source retention mechanism according to example embodiments of the present disclosure.

FIG. 5B depicts a perspective view of a source retention mechanism according to example embodiments of the present disclosure.

FIGS. 6A-C depict a crystal growth system that may utilize components according to example embodiments of the present disclosure;

FIG. 7 depicts a crystal growth system that may utilize components according to example embodiments of the present disclosure;

FIG. 8 depicts a crystal growth system that may utilize components according to example embodiments of the present disclosure;

FIG. 9 depicts a crystal growth system that may utilize components according to example embodiments of the present disclosure;

FIG. 10 depicts a crystal growth system that may utilize components according to example embodiments of the present disclosure;

FIG. 11 depicts a crystal growth system that may utilize components according to example embodiments of the present disclosure;

FIG. 12 depicts a crystal growth system that may utilize components according to example embodiments of the present disclosure;

FIG. 13 is a flowchart illustrating a method for creating a component for use in a crystal growth system according to example embodiments of the present disclosure.

FIG. 14 is a flowchart illustrating a method for creating a component for use in a crystal growth system according to example embodiments of the present disclosure.

FIG. 15 is a flowchart illustrating a method for creating a component according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Aspects of the present disclosure are directed to graphite structures used in crystal growth systems, such as silicon carbide crystal growth systems.

Some embodiments in accordance with the present disclosure relate to structures that may be used in crystal growth systems, including for example CVD, physical vapor transport (PVT), and hybrid systems.

Although TaC may extend the lifetime of graphite parts, it has limitations. For example, depositing TaC on graphite using a CVD deposition process may adequately coat the smaller hard graphite components in the crucible, while not adequately coating other graphite components in the crucible. In the grower-crucible system, there can be multiple graphite parts or components susceptible to degradation. These parts can vary greatly in size, shape, and cost. In some coating approaches, the expensive larger components which are not made from hard graphite, for example, cannot by protected from degradation. Another limitation of some coating approaches is a narrow thickness range of a coating, which is a feature constrained by the CVD chemistry being used. Other drawbacks of some coating approaches include high fabrication costs, large and specialized equipment for high temperature processing, highly toxic processing reagents, and corrosive waste byproducts. All these examples demonstrate the limited flexibility and scalability of some approaches including, for example, current approaches using a TaC deposition system.

Inventive concepts will now be described more fully hereinafter with reference to the accompanying drawings, in which examples of embodiments of inventive concepts are shown. Inventive concepts may, however, be embodied in many different forms and should not be construed as limited to the embodiments set forth herein. Rather, these embodiments are provided so that this disclosure will be thorough and complete, and will fully convey the scope of present inventive concepts to those skilled in the art. It should also be noted that these embodiments are not mutually exclusive. Components from one embodiment may be tacitly assumed to be present/used in another embodiment.

Methods for creating a component for use in a crystal growth system in accordance with the present disclosure may include heating an article comprising at least a metal layer on at least one surface; providing a source of carbon wherein a metal carbide layer is formed on the at least one surface of the article.

In some embodiments, the metal layer is made of a refractory metal. In some embodiments, the metal layer is made of chromium, hafnium, iridium, molybdenum, niobium, osmium, rhenium, rhodium, ruthenium, tantalum, titanium, tungsten, vanadium, zirconium, or a mixture thereof. In some embodiments, the article is made completely from a refractory metal. In some embodiments, the article is made completely of chromium, hafnium, iridium, molybdenum, niobium, osmium, rhenium, rhodium, ruthenium, tantalum, titanium, tungsten, vanadium, zirconium, or a mixture thereof. In some embodiments, the metal article is made of tantalum.

In some embodiments, the metal article is heated in a crucible. In some embodiments, the crucible is a crystal growth crucible.

In some embodiments, the source of carbon is at least one of: a crucible, a powder, a gas, a coating on the at least one surface, or a portion of the article. In some embodiments, the source of carbon is silicon carbide. In some embodiments, the silicon carbide is a powder. In some embodiments, the silicon carbide is at least a portion of a crucible. In some embodiments, the crucible includes at least one graphite plate. In some embodiments, the crucible includes two graphite plates. In some embodiments, the method further comprising pressing the article between the two graphite plates. In some embodiments, the article is heated to at least 2000° C.

In some embodiments, the component for use in a crystal growth system is an article for use in a chemical vapor deposition process. In some embodiments, the component for use in a crystal growth system is one of a susceptor assembly or an insulative cover. In some embodiments, the component for use in a crystal growth system is an article for use in a physical vapor transport process. In some embodiments, the component for use in a crystal growth system is one of a source, seed holder, crucible, source retention mechanism, lid, spacer ring, rod, liner, washer, shaft, porous barrier, or filter. In some embodiments, the component for use in a crystal growth system is an article for use in a process that is a hybrid of a chemical vapor deposition process and a physical vapor transport process. In some embodiments, the component for use in a crystal growth system is configured to operate at temperatures between 900° C. and 1700° C. In some embodiments, the component for use in a crystal growth system is configured to operate at temperatures between 1700° C. and 2600° C. In some embodiments, the component for use in a crystal growth system is configured to operate at temperatures between 2000° C. and 2600° C.

A component in accordance with the present disclosure may include a metal component having a metal carbide layer on at least one surface; wherein the metal carbide layer is formed by heating the metal article in a crucible with a source of carbon.

In some embodiments, the metal layer is made of a refractory metal. In some embodiments, the metal layer is made of chromium, hafnium, iridium, molybdenum, niobium, osmium, rhenium, rhodium, ruthenium, tantalum, titanium, tungsten, vanadium, zirconium, or a mixture thereof. In some embodiments, the article is made completely from a refractory metal. In some embodiments, the article is made completely of chromium, hafnium, iridium, molybdenum, niobium, osmium, rhenium, rhodium, ruthenium, tantalum, titanium, tungsten, vanadium, zirconium, or a mixture thereof. In some embodiments, the metal article is made of tantalum.

In some embodiments, the metal article is heated in a crucible. In some embodiments, the crucible is a crystal growth crucible. In some embodiments, the source of carbon is at least one of: a crucible, a powder, a gas, a coating on the at least one surface, or a portion of the article. In some embodiments, the source of carbon is silicon carbide. In some embodiments, the silicon carbide is a powder. In some embodiments, the silicon carbide is at least a portion of the a crucible. In some embodiments, the crucible includes at least one graphite plate. In some embodiments, the crucible includes two graphite plates. In some embodiments, the article is pressed between the two graphite plates. In some embodiments, the metal article is heated to at least 2000° C.

In some embodiments, the component for use in a crystal growth system is an article for use in a chemical vapor deposition process. In some embodiments, the component for use in a crystal growth system is one of a susceptor assembly or an insulative cover. In some embodiments, the component for use in a crystal growth system is an article for use in a physical vapor transport process. In some embodiments, the component for use in a crystal growth system is one of a source, seed holder, crucible, source retention mechanism, lid, spacer ring, rod, liner, washer, shaft, porous barrier, or filter. In some embodiments, the component for use in a crystal growth system is an article for use in a process that is a hybrid of a chemical vapor deposition process and a physical vapor transport process. In some embodiments, the component for use in a crystal growth system is configured to operate at temperatures between 900° C. and 1700° C. In some embodiments, the component for use in a crystal growth system is configured to operate at temperatures between 1700° C. and 2600° C. In some embodiments, the component for use in a crystal growth system is configured to operate at temperatures between 2000° C. and 2600° C.

Methods for creating a component for use in a crystal growth system in accordance with the present disclosure may include providing an component having at least a metal layer on at least one surface; applying a coating to the at least one surface; wherein the coating includes metal particles and a binder; heating the coated article with a source of carbon; wherein a metal carbide layer is formed on the at least one surface of the article.

In some embodiments, the component is made of graphite. In some embodiments, the component is made of metal. In some embodiments, the component is made of a refractory metal. In some embodiments, the component is made of chromium, hafnium, iridium, molybdenum, niobium, osmium, rhenium, rhodium, ruthenium, tantalum, titanium, tungsten, vanadium, zirconium, or a mixture thereof. In some embodiments, the component is made of tantalum.

In some embodiments, the metal layer is made of a refractory metal. In some embodiments, the metal layer is made of chromium, hafnium, iridium, molybdenum, niobium, osmium, rhenium, rhodium, ruthenium, tantalum, titanium, tungsten, vanadium, zirconium, or a mixture thereof. In some embodiments, the metal layer is made of tantalum. In some embodiments, the metal layer is contiguous. In some embodiments, the metal layer is over the entire article.

In some embodiments, the metal particles are a refractory metal. In some embodiments, the metal particles are chromium, hafnium, iridium, molybdenum, niobium, osmium, rhenium, rhodium, ruthenium, tantalum, titanium, tungsten, vanadium, zirconium, or a mixture thereof. In some embodiments, the metal particles are tantalum. In some embodiments, the metal particles are 10 microns or less in diameter.

In some embodiments, the binder is a thermally curable resin. In some embodiments, the method further includes curing the coating. In some embodiments, the method further includes thermally curing the coating. In some embodiments, the method further includes thermally curing the coating at 150° C. or greater. In some embodiments, the coating further comprises at least one compound that promotes the dispersion of the metal particles. In some embodiments, the coating further comprises at least one compound that promotes sintering. In some embodiments, the coating is applied by dip coating. In some embodiments, the coating further comprises a solvent.

In some embodiments, the metal article is heated in a crucible. In some embodiments, the crucible is a crystal growth crucible. In some embodiments, the source of carbon is at least one of: a crucible, a powder, a gas, a coating on the at least one surface, or a portion of the article. In some embodiments, the source of carbon is silicon carbide. In some embodiments, the silicon carbide is a powder. In some embodiments, the silicon carbide is at least a portion of a crucible. In some embodiments, the crucible includes at least one graphite plate. In some embodiments, the crucible includes two graphite plates. In some embodiments, the method further includes pressing the component between the two graphite plates. In some embodiments, the component is heated to at least 2000° C.

In some embodiments, the component for use in a crystal growth system is an article for use in a chemical vapor deposition process. In some embodiments, the component for use in a crystal growth system is one of a susceptor assembly or an insulative cover. In some embodiments, the component for use in a crystal growth system is an article for use in a physical vapor transport process. In some embodiments, the component for use in a crystal growth system is one of a source, seed holder, crucible, source retention mechanism, lid, spacer ring, rod, liner, washer, shaft, porous barrier, or filter. In some embodiments, the component for use in a crystal growth system is an article for use in a process that is a hybrid of a chemical vapor deposition process and a physical vapor transport process. In some embodiments, the component for use in a crystal growth system is configured to operate at temperatures between 900° C. and 1700° C. In some embodiments, the component for use in a crystal growth system is configured to operate at temperatures between 1700° C. and 2600° C. In some embodiments, the component for use in a crystal growth system is configured to operate at temperatures between 2000° C. and 2600° C.

A component in accordance with the present disclosure may include an article having a metal carbide layer on at least one surface; wherein the metal carbide layer is formed using a paint applied to the at least one surface and heating the article with the paint applied to the at least one surface in the presence of a source of carbon; wherein the paint is comprised of metal particles and a binder.

In some embodiments, the component is made of graphite. In some embodiments, the component is made of metal. In some embodiments, the component is made of a refractory metal. In some embodiments, the component is made of chromium, hafnium, iridium, molybdenum, niobium, osmium, rhenium, rhodium, ruthenium, tantalum, titanium, tungsten, vanadium, zirconium, or a mixture thereof. In some embodiments, the component is made of tantalum.

In some embodiments, the metal layer is made of a refractory metal. In some embodiments, the metal layer is made of chromium, hafnium, iridium, molybdenum, niobium, osmium, rhenium, rhodium, ruthenium, tantalum, titanium, tungsten, vanadium, zirconium, or a mixture thereof. In some embodiments, the metal layer is made of tantalum. In some embodiments, the metal layer is contiguous. In some embodiments, the metal layer is over the entire article.

In some embodiments, the metal particles are a refractory metal. In some embodiments, the metal particles are chromium, hafnium, iridium, molybdenum, niobium, osmium, rhenium, rhodium, ruthenium, tantalum, titanium, tungsten, vanadium, zirconium, or a mixture thereof. In some embodiments, the metal particles are tantalum. In some embodiments, the metal particles are 10 microns or less in diameter.

In some embodiments, the binder is a thermally curable resin. In some embodiments, the coating is cured. In some embodiments, the coating is thermally cured. In some embodiments, the coating is thermally cured at 150° C. or greater.

In some embodiments, the coating further comprises at least one compound that promotes the dispersion of the metal particles. In some embodiments, the coating further comprises at least one compound that promotes sintering. In some embodiments, the coating is applied by dip coating. In some embodiments, the coating further comprises a solvent. In some embodiments, the metal article is heated in a crucible. In some embodiments, the crucible is a crystal growth crucible.

In some embodiments, the source of carbon is at least one of: a crucible, a powder, a gas, a coating on the at least one surface, or a portion of the article. In some embodiments, the source of carbon is silicon carbide. In some embodiments, the silicon carbide is a powder. In some embodiments, the silicon carbide is at least a portion of a crucible. In some embodiments, the crucible includes at least one graphite plate. In some embodiments, the crucible includes two graphite plates. In some embodiments, the component is pressed between the two graphite plates. In some embodiments, the component is heated to at least 2000° C.

In some embodiments, the component for use in a crystal growth system is an article for use in a chemical vapor deposition process. In some embodiments, the component for use in a crystal growth system is one of a susceptor assembly or an insulative cover. In some embodiments, the component for use in a crystal growth system is an article for use in a physical vapor transport process. In some embodiments, the component for use in a crystal growth system is one of a seed holder, crucible, source retention mechanism, lid, spacer ring, rod, liner, washer, shaft, porous barrier, or filter. In some embodiments, the component for use in a crystal growth system is an article for use in a process that is a hybrid of a chemical vapor deposition process and a physical vapor transport process. In some embodiments, the component for use in a crystal growth system is configured to operate at temperatures between 900° C. and 1700° C. In some embodiments, the component for use in a crystal growth system is configured to operate at temperatures between 1700° C. and 2600° C. In some embodiments, the component for use in a crystal growth system is configured to operate at temperatures between 2000° C. and 2600° C.

A method for creating a component in accordance with the present disclosure may include forming the component using a viscous material including metal particles and a binder; and providing a source of carbon heating the part such that the part becomes solid metal carbide.

In some embodiments, the component is formed via 3D printing. In some embodiments, the component is formed by casting. In some embodiments, the component is formed by slip casting. In some embodiments, the component is formed by applying the viscous material to a support structure. In some embodiments, the component is formed by painting the viscous material on a sacrificial support structure. In some embodiments, comprising sintering the component. In some embodiments, the component is porous after the metal particles become sintered. In some embodiments, the component is non-porous after the metal particles become sintered. In some embodiments, the component is structural.

In some embodiments, the source of carbon is at least one of: a crucible, a powder, a gas, a coating on the at least one surface, or a portion of the article. In some embodiments, the source of carbon is silicon carbide. In some embodiments, the silicon carbide is a powder. In some embodiments, the silicon carbide is at least a portion of a crucible. In some embodiments, the crucible includes at least one graphite plate. In some embodiments, the crucible includes two graphite plates. In some embodiments, the method further includes pressing the component between the two graphite plates. In some embodiments, the component is heated to at least 2000° C.

In some embodiments, the metal particles are a refractory metal. In some embodiments, the metal particles are chromium, hafnium, iridium, molybdenum, niobium, osmium, rhenium, rhodium, ruthenium, tantalum, titanium, tungsten, vanadium, zirconium, or a mixture thereof. In some embodiments, the metal particles are tantalum. In some embodiments, the metal particles are 10 microns or less in diameter.

In some embodiments, the binder is a thermally curable resin. In some embodiments, the method further includes curing the coating. In some embodiments, the method further includes thermally curing the coating. In some embodiments, the method further includes thermally curing the coating at 150° C. or greater.

In some embodiments, the coating further comprises at least one compound that promotes the dispersion of the metal particles. In some embodiments, the coating further comprises at least one compound that promotes sintering. In some embodiments, the coating further comprises a solvent. In some embodiments, the metal article is heated in a crucible. In some embodiments, the crucible is a crystal growth crucible.

In some embodiments, the component for use in a crystal growth system is an article for use in a chemical vapor deposition process. In some embodiments, the component for use in a crystal growth system is one of a susceptor assembly or an insulative cover. In some embodiments, the component for use in a crystal growth system is an article for use in a physical vapor transport process. In some embodiments, the component for use in a crystal growth system is one of a source, seed holder, crucible, source retention mechanism, lid, spacer ring, rod, liner, washer, shaft, porous barrier, or filter. In some embodiments, the component for use in a crystal growth system is an article for use in a process that is a hybrid of a chemical vapor deposition process and a physical vapor transport process. In some embodiments, the component for use in a crystal growth system is configured to operate at temperatures between 900° C. and 1700° C. In some embodiments, the component for use in a crystal growth system is configured to operate at temperatures between 1700° C. and 2600° C. In some embodiments, the component for use in a crystal growth system is configured to operate at temperatures between 2000° C. and 2600° C.

A component in accordance with the present invention may include a viscous material comprising metal particles and a binder that has been heated in the presence of a source of carbon such that the viscous material becomes solid metal carbide.

In some embodiments, the component is formed via 3D printing. In some embodiments, the component is formed by casting. In some embodiments, the component is formed by slip casting. In some embodiments, the component is formed by applying the viscous material to a support structure. In some embodiments, the component is formed by painting the viscous material on a sacrificial support structure. In some embodiments, the component is sintered. In some embodiments, the component is porous after the metal particles become sintered. In some embodiments, the component is non-porous after the metal particles become sintered. In some embodiments, the component is structural.

In some embodiments, the source of carbon is at least one of: a crucible, a powder, a gas, a coating on the at least one surface, or a portion of the article. In some embodiments, the source of carbon is silicon carbide. In some embodiments, the silicon carbide is a powder. In some embodiments, the silicon carbide is at least a portion of a crucible. In some embodiments, the crucible includes at least one graphite plate. In some embodiments, the crucible includes two graphite plates. In some embodiments, the component is pressed between the two graphite plates. In some embodiments, the component is heated to at least 2000° C.

In some embodiments, the metal particles are a refractory metal. In some embodiments, the metal particles are chromium, hafnium, iridium, molybdenum, niobium, osmium, rhenium, rhodium, ruthenium, tantalum, titanium, tungsten, vanadium, zirconium, or a mixture thereof. In some embodiments, the metal particles are tantalum. In some embodiments, the metal particles are 10 microns or less in diameter.

In some embodiments, the binder is a thermally curable resin. In some embodiments, the coating is cured. In some embodiments, the coating is thermally cured. In some embodiments, the coating is thermally cured at 150° C. or greater.

In some embodiments, the coating further comprises at least one compound that promotes the dispersion of the metal particles. In some embodiments, the coating further comprises at least one compound that promotes sintering. In some embodiments, the coating further comprises a solvent. In some embodiments, the metal article is heated in a crucible. In some embodiments, the crucible is a crystal growth crucible.

In some embodiments, the component for use in a crystal growth system is an article for use in a chemical vapor deposition process. In some embodiments, the component for use in a crystal growth system is one of a susceptor assembly or an insulative cover. In some embodiments, the component for use in a crystal growth system is an article for use in a physical vapor transport process. In some embodiments, the component for use in a crystal growth system is one of a source, seed holder, crucible, source retention mechanism, lid, spacer ring, rod, liner, washer, shaft, porous barrier, or filter. In some embodiments, the component for use in a crystal growth system is an article for use in a process that is a hybrid of a chemical vapor deposition process and a physical vapor transport process. In some embodiments, the component for use in a crystal growth system is configured to operate at temperatures between 900° C. and 1700° C. In some embodiments, the component for use in a crystal growth system is configured to operate at temperatures between 1700° C. and 2600° C. In some embodiments, the component for use in a crystal growth system is configured to operate at temperatures between 2000° C. and 2600° C.

In some embodiments, the process disclosed herein may be used to create a coating, surface treatment, or subsurface treatment for any part of a crystal growth system, including but not limited to a source or a baffle. Such parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure).

In the drawings and specification, there have been disclosed typical embodiments and, although specific terms are employed, they are used in a generic and descriptive sense only and not for purposes of limitation of the scope set forth in the following claims.

One example of a crystal growth system is chemical vapor deposition (CVD). CVD is a process used to grow high-quality crystals of materials, especially semiconductors, metals, and other compounds, by transporting chemical species in vapor form from a source to a growth site. In CVD, a solid material (source) is heated in the presence of a transport agent, usually a halogen gas like iodine, chlorine, or bromine. The source material reacts with the transport agent to form a volatile compound, which is then transported to a cooler region of the chamber. Upon reaching the cooler region, the vaporized material decomposes or reacts to deposit the pure solid, resulting in crystal growth.

Another example of a crystal growth system is physical vapor transport (PVT). PVT is a process used to grow single crystals from the vapor phase without the use of a liquid or solution medium. This process involves sublimating a solid material, transporting the vapor to a cooler region of the chamber, and allowing the vapor to condense and crystallize on a substrate or seed crystal. Crystal growth systems may also be a hybrid of CVD and PVT processes.

Crystal growth systems may employ ultra-high temperatures. For example, systems for bulk crystal growth may reach temperatures in the range of 1700° C. to 2600° C. or higher. Also for example, systems for epitaxial growth may reach temperatures in the range of 900° C. to 1700° C.

One or more baffle structures may be used in crystal growth systems and deposition systems (e.g., epitaxial reactors), such as silicon carbide crystal growth sublimation systems to accommodate the transport (e.g., kinetic factors) of source material vapor while enhancing control over a thermal gradient or chemical environment. For instance, in some examples, a baffle may accommodate a transport of vapor (e.g., source material vapor) while providing a physical separation of chemical and/or thermal environments between a sublimating source material and a seed material experiencing deposition at a growth front. Such baffle structures may be created from or may have a coating created thereon according to certain embodiments of the present disclosure.

In some embodiments, the crystal growth system may include a baffle within the crystal growth chamber that may be spaced apart from the silicon carbide vapor source material.

In some embodiments, the baffle includes a porous material, such as porous graphite. In some examples, at least a portion of the baffle has a porosity of greater than about 50% by volume, such as greater than about 70% by volume, such as greater than 80% by volume. Porosity by volume expressed as a percentage refers to the percentage of the volume of voids in the baffle relative to the total volume of the material.

In some embodiments, the baffle includes one or more apertures defined through a thickness of the baffle. As used herein, an “aperture” is a defined opening, space, perforation, hole, or void in a structure that extends from one exterior surface of a structure to another exterior surface of the structure. In some embodiments, each of the one or more apertures provides a path through the baffle for transport of vapor from the silicon carbide source material to the seed crystal without having significant crystal growth formation in the aperture.

In some embodiments, the baffle has a long dimension that is generally non-perpendicular to the growth surface of the seed crystal. In some embodiments, the baffle has a thickness in a direction of vapor transport through the baffle. As used herein, the “width” or “width dimension” refers to a dimension of a baffle, an aperture, or other structure that runs in a plane that is perpendicular to the transport direction of vapor to the crystal growth system. The “long dimension” of a baffle, an aperture, or other structure refers to the longest dimension (e.g., greatest in magnitude) of the structure.

In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. As used herein, a baffle provides non-uniform vapor transport when vapor is transported through a first portion of the baffle at a first rate and is transported through a second portion of the baffle at a second rate. The first rate is different from the second rate. For instance, a baffle may include a first portion with one or more apertures that transports vapor at a first rate. The baffle may include a second portion without apertures that transports vapor at a second rate.

In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle. In some examples, the first plurality of baffles are in a central portion of the baffle and the second plurality of baffles are in a peripheral portion of the baffle. In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, at least one surface of the baffle may be flat, whereas in other examples, at least one surface of the baffle may be concave, convex, angled, or other topographies. In some examples, the surface of the baffle closest to the seed crystal may have a particular topography and the surface of the baffle furthest from the seed crystal may have a different topography.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate includes a first aperture and a second baffle plate including a second aperture. In some examples, the first aperture is aligned with the second aperture. In some examples, the first aperture is not aligned with the second aperture. In some examples, the first aperture has a different width relative to the second aperture. In some examples, the baffle includes a first baffle plate including a first material and a second baffle plate including a second material. In some examples, the first baffle plate includes graphite and the second baffle plate includes a source material (e.g., carbon source material, carbon source material, etc.). In some examples, the baffle includes a third baffle plate, wherein the third baffle plate includes the first material. In some examples, the second baffle plate is arranged between the first baffle plate and the third baffle plate. In some examples, the first material includes graphite and the second material includes a source material (e.g., silicon carbide source material and/or carbon source material (e.g., graphite).

In some examples having a plurality of baffle structures, the baffle structures may be in contact with one another. In some examples, the plurality of baffle structures may not be in contact with one another. In some examples, the plurality of baffle structures may include other structures between them.

In some examples, the baffle includes graphite. In some examples, the baffle includes a coating on the graphite. In some examples, the coating is only on a portion of the baffle. In some examples, the baffle includes multiple coatings, including different regions of the baffle having distinct coatings. In some examples, the coating is a pyrolytic coating. In some examples, the coating includes tantalum carbide. In some examples, the graphite is porous graphite.

In some examples, the baffle is spaced apart from the seed holder and is not coupled to the seed holder. In some examples, the baffle is coupled to a side wall of the crucible.

In addition, the baffle, or a portion thereof, may potentially act as a second source (e.g., a carbon source). For instance, if a reactive material is used as a baffle, the baffle may be etched such that the baffle contributes positively to species interacting with the seed crystal during a growth process. The baffle, or a portion thereof, can be made of a reactive material that captures parasitic silicon carbide, or silicon carbide that crystallizes in an undesirable location, and act as a dynamic source if the captured silicon carbide is sublimated, if desired. Further, the baffle may act as an additional gas injection site for process gases.

In addition, if a large surface area of material that is non-reactive or inert with respect to carbon and silicon species is provided, the inert material may provide a catalytic surface that facilitates gas-gas reactions (e.g., to change ratios of silicon, carbon, and/or species containing silicon and/or carbon in the vapor). That is, gas stoichiometry in the vicinity of the baffle may be brought towards equilibrium. This may facilitate enhanced growth rates and less material waste. In some embodiments, at least a portion of the baffle may have a chemically active surface or coating that may be used to reduce contaminates, impurities, and inclusions in vapor transported through the baffle.

Examples of crystal growth systems, including crystal growth systems incorporating exemplary baffle structures are disclosed in U.S. patent application Ser. No. 18/962,454, filed Nov. 27, 2024, which is incorporated herein by reference.

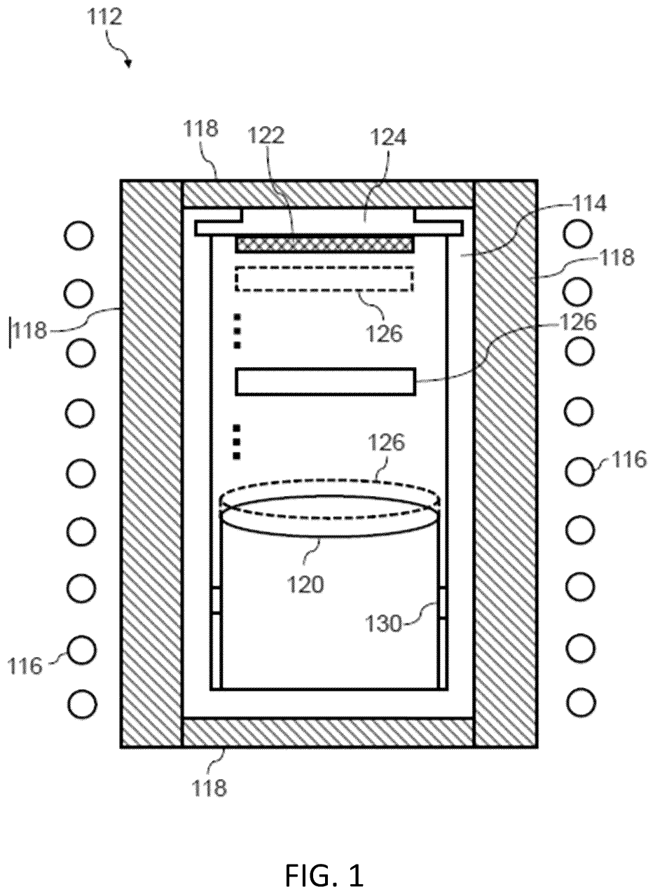

FIG. 1 is a cross-sectional schematic diagram of a crystal growth system 112 adapted for use in a crystal growth process of the type contemplated by certain embodiments of the disclosure. The crystal growth system 112 includes a reaction crucible 114 (also referred to as a susceptor or growth cell) and a plurality of induction coils 116 adapted to heat the reaction crucible 114 when electrical current is applied. Alternatively, a resistive heating approach may be applied to the heating of the reaction crucible 114. Using any competent heating mechanism and approach, the temperature within the crystal growth system 112 may be controllable. The reaction crucible 114 may be, at least in part, a graphite structure.

The crystal growth system 112 may also include one or more gas inlet and gas outlet ports and associated equipment allowing the controlled introduction and evacuation of gas from an environment surrounding the reaction crucible 114. The introduction and evacuation of various gasses to or from the environment surrounding the reaction crucible 114 may be accomplished using a variety of inlets/outlets, pipes, valves, pumps, gas sources, and controllers. It will be further understood by those skilled in the art, using the disclosures provided herein, that the crystal growth system 112 may further incorporate in certain embodiments a water-cooled quartz vessel.

The reaction crucible 114 may be surrounded by an insulation material 118. The composition, size, and placement of the insulation material 118 will vary with an individual crystal growth system, such as the crystal growth system 112 of FIG. 1, to define and/or maintain desired thermal gradients (both axially and radially) in relation to the reaction crucible 114. For purposes of clarity, the term, “thermal gradient,” will be used herein to describe one or more thermal gradient(s) associated with the reaction crucible 114. Those skilled in the art, using the disclosures provided herein, recognize that “the thermal gradient” established in embodiments of the disclosure will contain (or may be further characterized as having) axial and radial gradients, or may be characterized by a plurality of isotherms.

Prior to establishment of the thermal gradient, the reaction crucible 114 is loaded with a source material 120 (e.g., silicon carbide vapor source material, such as a silicon carbide powder or solid silicon carbide source). As such, the reaction crucible 114 includes one or more portions, at least one of which is capable of providing the source material 120. The source material 120 may be held in a lower portion of the reaction crucible 114, as is common for one type of crystal growth system, such as the crystal growth system 112 of FIG. 1.

A seed material 122 may be placed above or in an upper portion of the reaction crucible 114. The seed material 122 may take the form of a silicon carbide seed wafer having a diameter, for instance, from about 50 mm to about 310 mm. A silicon carbide crystal boule will be grown from the seed material 122 during a crystal growth process.

In the embodiment illustrated in FIG. 1, a seed holder 124 is used to hold the seed material 122. The seed holder 124 is securely attached to the reaction crucible 114 in an appropriate fashion. For example, in the orientation illustrated in FIG. 1, the seed holder 124 is attached to an uppermost portion of the reaction crucible 114 to hold the seed material 122 in a desired position. In some embodiments, the seed holder 124 is fabricated from carbon (e.g., graphite). The attachment of the seed material 122 (e.g., a seed wafer) to the seed holder 124 within the crystal growth system 112 may be made, for instance, by a uniform thermal contact. Various techniques may be used to implement a uniform thermal contact. For example, the seed material 122 may be placed in direct physical contact with the seed holder 124, or an adhesive may be used to fix the seed material 122 to the seed holder 124, so as to provide uniform conductive and/or radiative heat transfer over substantially the entire area between the seed material 122 and the seed holder 124.

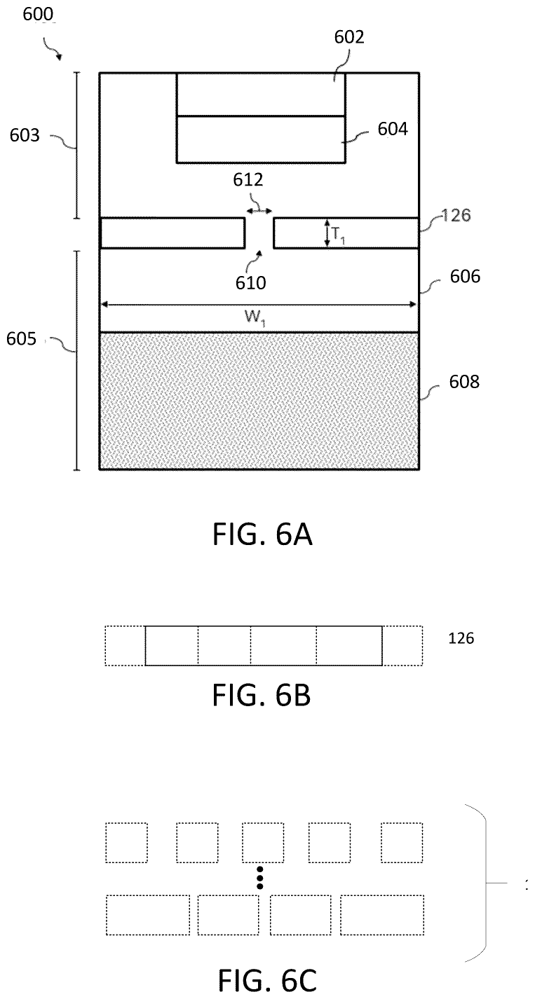

According to example aspects of the present disclosure, the crystal growth system 112 may include a baffle 126 that may be situated on the source material 120 or at any other location within the crystal growth system 112. The baffle 126 may provide a mechanism for transport of source vapor or other process gas during sublimation of the source material 120. The baffle 126 may filter or otherwise reduce impurities from the source material 120 that may inadvertently sublimate in a crystal growth process. The baffle may have any spatial orientation relative to the source material 120, the seed material 122, and/or the reaction crucible 114. The baffle 126 may include any of the baffles discussed in relation to FIGS. 6A-12.

Further, the crystal growth system 112 may optionally include the source material holder 130. The source material holder 130 may be, for example, one or more graphite components within the reaction crucible 114 that brace or support the shaped solid source material 120. In some embodiments, the source material holder 130 may be attached to the inner walls of the reaction crucible 114, as shown in FIG. 1.

FIG. 1 depicts a coordinate system having an x-axis as a horizontal axis, a y-axis that is in and out of the page, and a z-axis that is a vertical axis. A width dimension refers to a dimension along the x-axis or y-axis. A thickness dimension refers to a dimension along the z-axis. For the sake of clarity, any dimension along the x-axis or y-axis may be considered a width dimension regardless of whether it is the shortest or longest dimension in a plane defined by the x-axis and y-axis.

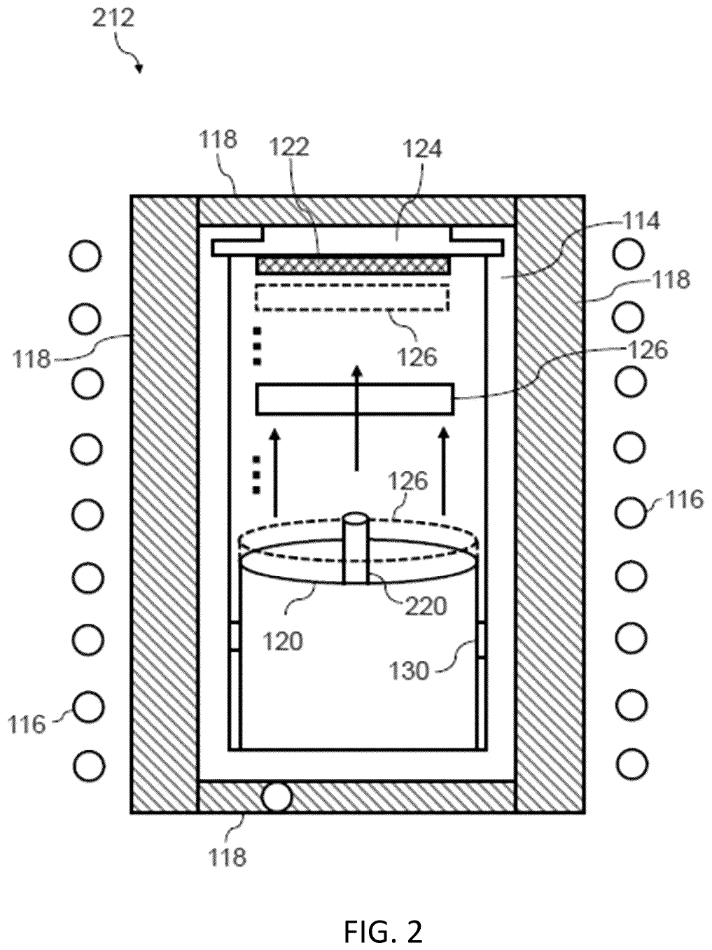

In one example embodiment, shown in FIG. 2, the crystal growth system 132 may be similar to that shown in FIG. 1, but may also include an inlet 134 for introducing a dopant (e.g., N₂) to the reaction crucible 114. The inlet 134, may be, for example, a tube, pipe, vent, or the like. In some embodiments, the source material 120 may surround the inlet 134. For example, in some embodiments, the source material 120 may include a channel through which the inlet 134 is provided. In other embodiments, the source material 120 may include a plurality of subcomponents (attached or detached) which surround the inlet 134. The inlet 134 may be connected to a dopant-containing gas source (not shown) and configured to introduce the dopant-containing gas to the reaction crucible 114. An example of a dopant-containing gas is nitrogen.

The crystal growth system 132 may include the baffle 126 that may be situated within the reaction crucible 114. The baffle 126 may provide a mechanism for the transport of source vapor during sublimation of the source material 120. The baffle 126 may have any spatial orientation relative to the source material 120, the seed material 122, and/or the reaction crucible 114. The baffle 126 may filter or otherwise reduce impurities from the source material 120 that may inadvertently sublimate in a crystal growth process. The baffle 126 may include any of the baffles discussed in relation to FIGS. 6A-12.

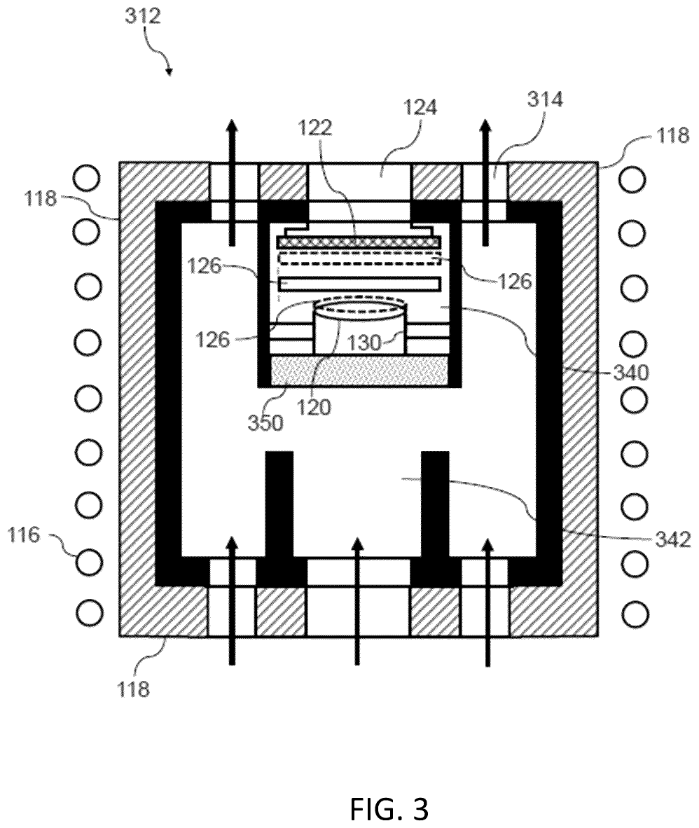

In another example embodiment, shown in FIG. 3, the crystal growth system 142 may be a continuous feed PVT (CF-PVT) system. In a CF-PVT system, such as the crystal growth system 142 of FIG. 3, the reaction crucible may include an upper chamber 144 and a lower chamber 146. The upper chamber 144 may include the source material 120 and the seed material 122. The upper chamber 144 may be separated from the lower chamber 146 by a foamed structure 150. The foamed structure 150 may be formed, for example, from a gas-permeable graphite foam. The source material 120 may be placed on the foamed structure 150 within the upper chamber 144. A gaseous silicon source (e.g., trimethylsilane diluted in argon) may be supplied to the lower chamber 146. As the gaseous silicon source is transported through the foamed structure 150, it may react with a carbon source within the foamed structure 150 (e.g., graphite) to form silicon carbide. A CF-PVT system, such as the crystal growth system 142 of FIG. 3, combines a PVT process for the growth of single crystals and high temperature chemical vapor deposition (HTCVD) processes for the in-situ formation and continuous feeding of a high purity polycrystalline source. A CF-PVT system, such as the crystal growth system 142 of FIG. 3, may be particularly useful for growing 3C silicon carbide.

The crystal growth system 142 may include a baffle 126 that may be situated within the upper chamber 144 of the reaction crucible. The baffle 126 may provide a mechanism for the transport of source vapor during sublimation of the source material 120. The baffle 126 may filter or otherwise reduce impurities from the source material 120 that may inadvertently sublimate in a crystal growth process. The baffle 126 may have any spatial orientation relative to the source material 120, the seed material 122, and/or the upper chamber 144 of the reaction crucible. The baffle 126 may include any of the baffles discussed in relation to FIGS. 6A-12.

In any of the embodiments shown in FIGS. 1-3, the crystal growth systems 112, 132, 142, and/or the reaction crucible 114 may be implemented in a number of different geometries, or any suitable configurations, and may hold the source material 120 accordingly. Thus, while embodiments of the present disclosure may be illustrated with certain designs of the reaction crucible 114, the scope of the present disclosure is not limited to such designs but will find application in different crystal growth system designs using many different types of reaction crucibles. In some examples, the crystal growth processes (e.g., the processes conducting in any of the embodiments shown in FIGS. 1-3) may be conducted at process temperatures in a range of 1700° C. to about 2600° C.

As shown in FIG. 1, the baffle 126 or baffle elements may be located on the source material, may be spaced apart from the source material 120 and/or the seed material 122, or may be proximate the seed material 122. In some embodiments, the system 112 may include any number of baffles or baffle elements 126 without deviating from the scope of the present disclosure. In some embodiments, the source material 120 may have a baffle 126 or baffle element incorporated therein.

Example silicon carbide source materials are disclosed in U.S. Provisional Application Ser. No. 63/689,294, filed on Aug. 30, 2024 and in U.S. Provisional Application Ser. No. 63/689,291, filed on Aug. 30, 2024, both of which are incorporated herein by reference.

The use of 3D printing to create parts and structures to be used in a crystal growth system or the source is disclosed in U.S. Provisional Application Ser. No. 63/689,298, filed on Aug. 30, 2024, which is incorporated herein by reference.

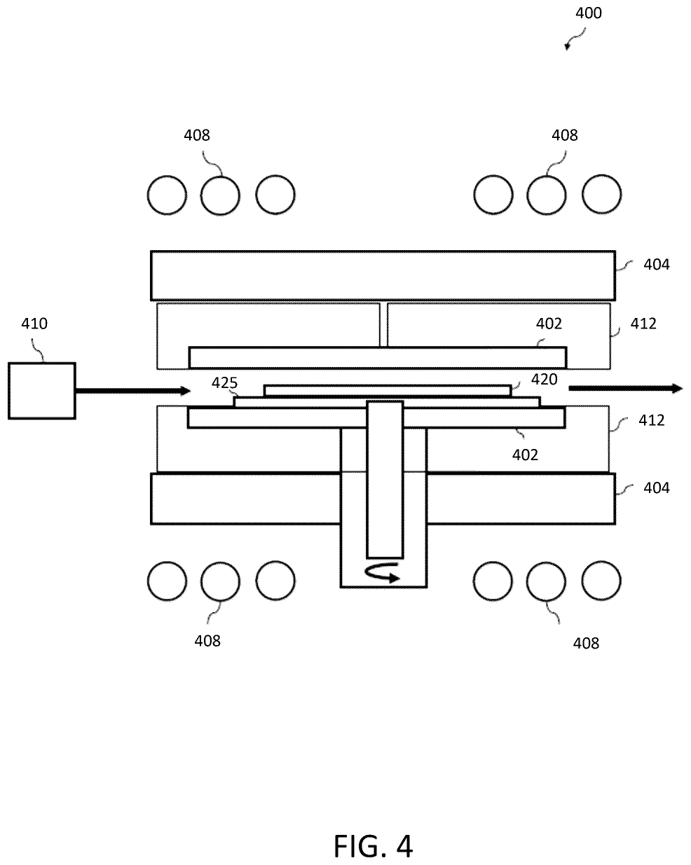

FIG. 4 depicts an example deposition system 400 (e.g., epitaxial reactor) that may include structures according to example embodiments of the present disclosure. The deposition system 400 may be a horizontal, hot wall, flow through, warm wall, and shower head CVD system as shown including a susceptor assembly 402, a quartz tube 404 defining a through passage 406, an electromagnetic frequency (EMF) generator 408 (for example, including a power supply and an RF coil surrounding the tube 404) and a process gas supply system 410. An insulative cover 412 may be provided about the susceptor assembly 402 in addition to or in place of the quartz tube 404 The deposition system 400 may be used to form a layer or film (e.g., epitaxial layer) on a workpiece 420 (e.g., a silicon carbide semiconductor wafer). In some examples, the deposition process using the deposition system 400 may occur at a process temperature in a range of about 900° C. to about 1700° C. While only a single workpiece 420 is shown in FIG. 4, the system 400 may be adapted to form films concurrently on multiple workpieces without deviating from the scope of the present disclosure.

The workpiece 420 may be on a workpiece holder 425. The workpiece holder 425, in some examples, may be coupled to a rotation shaft to provide rotation of the workpiece 420 during processing.

In some embodiments, the process gas supply system 410 may supply a process gas into and through the susceptor assembly 402 as discussed below. The EMF generator 408 inductively heats the susceptor assembly 402 to provide a hot zone in the susceptor assembly 402 where deposition reactions take place. The process gas continues through and out of the susceptor assembly 402 as an exhaust gas which may include remaining components of the process gas as well as reaction by-products, for example.

The susceptor assembly 402 and/or the insulative cover 412 may be, at least in part, a structure having a metal carbide coating. In some embodiments, the susceptor assembly 402 and/or the insulative cover 412 may be a structure according to example embodiments of the present disclosure.

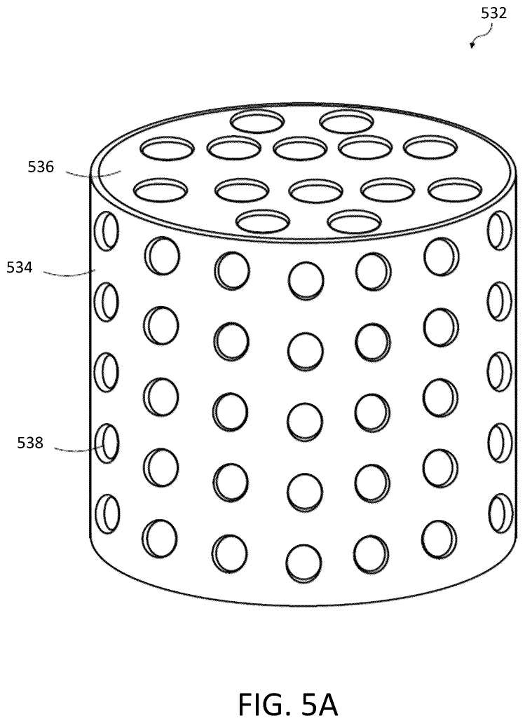

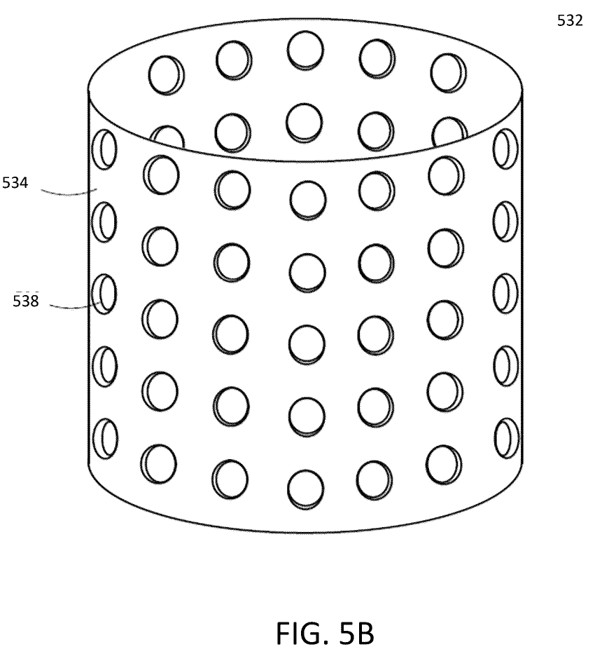

Crystal growth systems may also include source retention mechanisms. Example embodiments of source retention mechanisms are shown in FIGS. 5A and 5B. In FIG. 5A, the source retention mechanism 532 contains cylindrical side walls 534, a cap 536, and channels 538 formed in the side walls 534 and cap 536. As shown in FIG. 5A, the channels may all have the same or a similar diameter. In some embodiments, the diameters of the channels may be different and designed based on desired vapor flow paths and flowrates. For example, in some embodiments, the cap may have larger channels, or even one large central channel, relative to smaller or no peripheral channels.

The retention mechanism can be used to contain a source material, particularly when it is formed from multiple separate shaped solids (e.g., spheres). The channels 538 allow sublimated vapor to escape into the main chamber of the reaction crucible where they can reach the seed material or growing crystal. The channels may be designed/located to control the vapor flow within the crucible. For example, they can direct the vapor to specific parts of the seed material or growing crystal. In some embodiments, the channels in the side walls 534 may be omitted so that sublimated vapor can only exit through the channels in the cap 536. In some embodiments, the cap 536 may be omitted, as shown in FIG. 5B. In some embodiments, rather than, or in addition to, channels 538, the source walls and/or cap of the retention mechanism that may be made from a highly porous material that the sublimated vapor can escape through.

In some embodiments, it may be desired to restrict vapor flow from either the sides or the top. As such, the sides or top of the retention mechanism may be formed from a material with no or relatively low porosity. The retention mechanism may be formed from graphite, silicon carbide, or any other suitable material. When the retention mechanism is formed from silicon carbide, it may act as an additional solid source structure. The retention mechanism may be sized to fit within the inner walls of the crucible. The retention mechanism may contact the sidewalls of the crucible or may be spaced apart from them, leaving paths for vapor flow radially outward from the retention mechanism.

In any of the simplified crystal growth systems with a baffle 126 depicted in FIGS. 6A-12 the baffle 126 may provide vapor transport of a silicon carbide source vapor through a first portion of the baffle 126 at a first rate. In some embodiments, the silicon carbide vapor may be transported through a second portion of the baffle 126 (e.g., including one or more apertures), at a second rate. The first rate may be different than the second rate. For example, the baffle 126 may provide an avenue for source vapor to diffuse through the material of the baffle 126 at a first rate, while source vapor is transported through an aperture unimpeded by the material of the baffle 126 at a second rate. In some embodiments, the baffle 126 may be spaced apart from the seed holder 602 and is not coupled to the seed holder 602. In some embodiments, the baffle 126 may impede or otherwise alter heat transfer or thermal energy within the crystal growth chamber in a crystal growth process.

In some embodiments, the baffle 126 may be, at least partially, made of graphite. In some embodiments, the baffle 126 made at least partially of graphite may include a coating on at least a portion of the graphite. In some embodiments, the coating on the baffle 126 made of graphite may be a pyrolytic coating. In some embodiments, the coating on the baffle 126 made of graphite may be tantalum carbide. In some embodiments, the coating on the baffle 126 may hinder particulate matter larger than the source vapor from reaching a seed crystal 604. The seed crystal 604 may be a silicon carbide seed crystal. In some embodiments, the baffle 126 may be porous graphite. Porous graphite may provide a less hindered pathway for source vapor to diffuse through.

In some embodiments, the baffle 126 may be spaced apart from a seed holder 602 and is not coupled to the seed holder 602. In some embodiments, the baffle 126 may be spaced apart from a source material 608 and is not coupled to the source material 608. The source material 608 may be a silicon carbide vapor source material. In some embodiments, the baffle may be coupled to a side wall of a crucible 606.

FIG. 6A depicts a simplified view of a crystal growth system 600 according to example aspects of the present disclosure. The crystal growth system 600 includes the seed holder 602 configured to hold the seed crystal 604. The seed crystal 604 may provide a growth surface for growth of the silicon carbide crystalline material in a crystal growth process. The crystal growth system 600 includes the crucible 606 defining a crystal growth chamber. The crystal growth system 600 includes the source material 608. The crystal growth system 600 includes the baffle 126 within the crystal growth chamber that is spaced apart from the source material 608. In some embodiments, the baffle 126 may extend between the inner walls of the crucible 606, such that the crucible 606 is bisected or divided into an upper portion 603 and a lower portion 605 by the baffle 126. The upper portion 603 and the lower portion 605 may have the same or different volumes. In some examples, the baffle 126 may be coupled to a side wall of the crucible 606. In some examples, the baffle 126 may not fully extend between the inner walls of the crucible 606.

The baffle 126 has a long dimension (e.g., width) W1 and a thickness T1. The thickness T1 is in a general direction of vapor transport through the baffle 126. In some embodiments, the long dimension W1 is in a direction that is non-perpendicular to the growth surface of the seed crystal 604.

FIG. 6B depicts a simplified view of baffle 126 according to some aspects of the present disclosure. As shown in FIG. 6B, baffle 126 may include apertures, and may extend to the side walls of the crucible, or may not extend to the sidewalls of the crucible.

FIG. 6C depicts a simplified view of baffle 126 according to some aspects of the present disclosure. As shown in FIG. 6C, baffle 126 may include multiple baffle structures, which may be spaced apart from one another or may be in contact with one another.

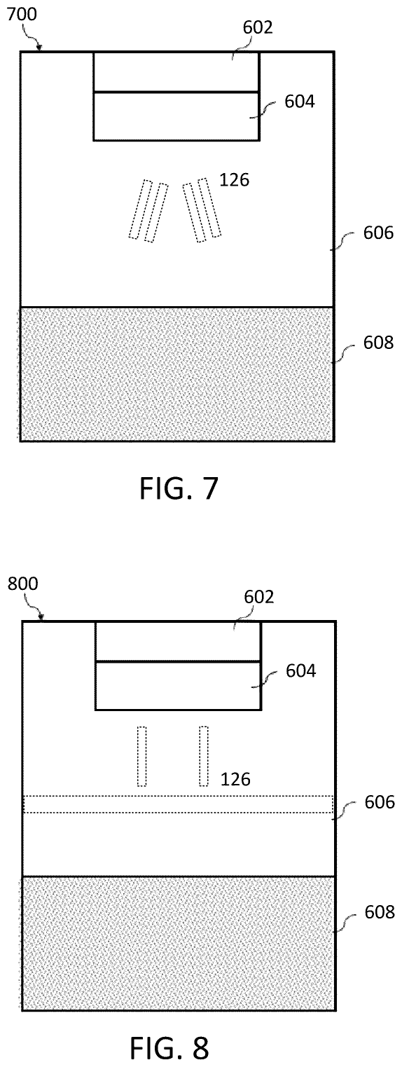

FIGS. 7, 8, 9, 10, 11, and 12 depict simplified views of baffle 126 according to some aspects of the present disclosure in the context of crystal growth systems 700, 800, 900, 1000, 1100, and 1200. As shown in FIG. 7, in some embodiments of the present disclosure, baffle 126 may include one or more baffle plates, in any orientation relative to the seed holder 602 or the source material 608. As shown in FIG. 8, in some embodiments of the present disclosure, baffle 126 may include two or more baffle structures, whether of the same type or of differing types, and such baffle structures may be of differing orientations relative to each other.

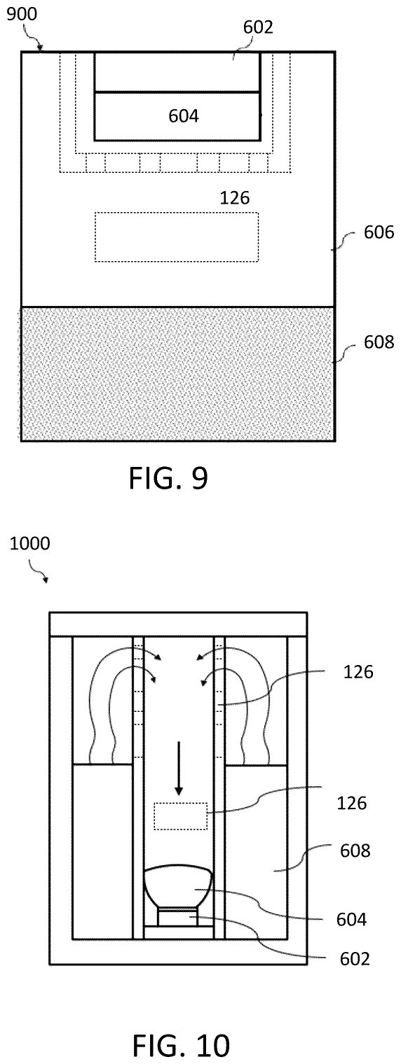

As shown in FIG. 9, in some embodiments of the present disclosure the crystal growth system 900 includes a baffle, the seed holder 602, the seed crystal 604, the crucible 606, and the source material 608. An element of the baffle 126 may be positioned such that the baffle 126 extends around at least three sides of the seed crystal 604, with the longest dimension located below the seed crystal 604. The baffle 126 may be referred to as a shell structure as it provides a shell around the seed crystal 604. The baffle 126 may be graphite, such as porous graphite. The baffle 126 may include one or more apertures that assist in the transport of source vapor from the source material 608 to the seed crystal 604, or may not include any apertures. Baffle 126 may also include additional elements, such as any of the exemplary baffles contemplated by the present disclosure, such as any of the baffles depicted in FIGS. 1-8, and such additional elements may be situated between the source material 608 and the seed crystal 604.

As shown in FIG. 10, example crystal growth system 1000 includes a baffle 126, a seed holder 602, a seed crystal 604, a crucible 606, and the source material 608. The baffle 126 may include a tubular baffle structure. The seed crystal 604 may be within the tubular baffle 126. The baffle 126 may be graphite, such as porous graphite. The baffle 126 may include one or more apertures that assist in the transport of source vapor from the source material 608 to the seed crystal 604, or may not include any apertures. Baffle 126 may also include additional elements, such as any of the exemplary baffles contemplated by the present disclosure, such as any of the baffles depicted in FIGS. 1-8, and such additional elements may be situated between the source material 608 and the seed crystal 604.

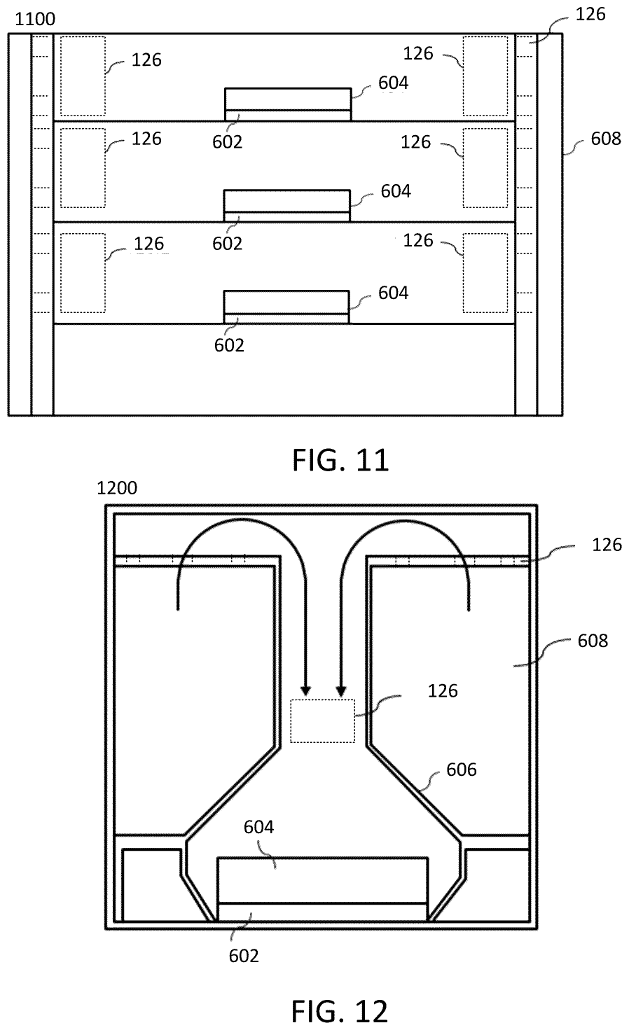

As shown in FIG. 11 example crystal growth systems 1100 may be used to grow a plurality of silicon carbide boules according to example embodiments of the present disclosure. In FIG. 11, the crystal growth system 1100 includes a plurality of seed holders 602 and seed crystals 604 arranged in different crystal growth chambers. A baffle 126 may separate the seed crystals 604 from a source material 608. As depicted in FIG. 11, the baffle 126 may include one or more apertures to assist with vapor transport from the source material 608 to the seed crystals 604. The apertures may have a shape and/or arrangement as any of the apertures provided herein. In some embodiments, as depicted in FIG. 11, the crystal growth system 1100 may include one or more additional baffles elements in each chamber. The additional baffle elements 126 may be arranged between the source material 608 and the seed crystal 604 in each chamber. Each of the one or more additional baffles elements 126 may include any of the baffles contemplated by the present disclosure, such as any of the baffles depicted in FIGS. 1-8.

FIG. 12 depicts example crystal growth systems 1200 according to example embodiments of the present disclosure. In FIG. 12, the crystal growth system 1200 includes a seed holder 602 and a seed crystal 604 arranged within a crucible 606. The crucible 606 may have one or more angled sidewalls. The crystal growth system 1200 includes a source material 608. The baffle 126 may be on top of the source material 608 and may separate the source material 608 from the reaction chamber defined by the crucible 606. As depicted in FIG. 12, the baffle 126 may include one or more apertures to assist with vapor transport from the source material 608 to the seed crystal 604. The apertures may have a shape and/or arrangement as any of the apertures provided herein. The system 1200 may further include additional baffle elements 126. The second baffle may be in the transport path between the source material 608 and the seed crystal 604. The second baffle 126 may include any of the baffles contemplated by the present disclosure, such as any of the baffles depicted in FIGS. 1-8.

In any crystal growth system incorporating aspects of the present disclosure, including exemplary crystal growth systems shown in FIGS. 1-3 and 6A-12, a baffle system may include single or multiple elements that may effect, alter, or provide a temperature gradient in a desired manner relative to the crystal growth surface. Such exemplary baffle systems may also effect, alter, or provide a vapor pressure gradient, vapor flux, or vapor flow. Such vapor pressure gradient, vapor flus, or vapor flow may be between any of the following: a SiC source, multiple SiC sources, one or more secondary Si or SiC sources, or one or more dopant sources. Such vapor pressure gradient, vapor flus, or vapor flow may be relative to the crystal growth surface, a side surface of the crystal, areas within the crystal growth system susceptible to parasitic growth, filtering structures, or other inclusions from the crystal. In some embodiments, different elements of the baffle system may provide different features. For example, a baffle system may include one or more elements that perform one or more of the following functions, which may be present in any combination: filtering; acting as a secondary source, for example a graphite element that provides a graphite source; effecting, altering, or providing a temperature gradient; effecting altering, or providing a vapor pressure gradient. In some embodiments, a baffle system may include one or more elements with apertures, pores, voids, cavities, indentations, and/or protrusions. In some embodiments, a baffle system may include one or more elements that may be coated in whole or in part with a carbide coating, including TaC. A baffle system may include one or more elements coated, or having portions coated, with a coating, or multiple coatings, or a patterned coating, for example, to achieve desired sublimation if acting as a secondary source or to reduce sublimation if not intended to serve as a secondary source. Individual baffles or elements in a baffle system can serve duplicate or different functions.

Aspects of the present disclosure relate to novel process for creating stronger multi-use parts, and parts with finer machining features than are allowed in graphite. Such parts may be made from metal (e.g., tantalum) and then carburizing those parts, converting the parts completely to metal carbide (e.g., tantalum carbide) or creating a metal carbide layer on the parts. Such parts may be pure ceramic. Such parts may not be as susceptible to etching as graphite parts and may allow for part geometry impossible with graphite parts.

Aspects of the present disclosure utilize carbon in vapor that reacts with solid metal (e.g., tantalum). This process may be completed in a crystal growth system. This process may also utilize any furnace able to provide the proper temperature and other conditions to allow the process to proceed.

In one process in accordance with certain aspects of the present disclosure, metal parts are placed into a crucible. Such metal parts may be created with known metal machining techniques. Such metal parts may be made, for example, of tantalum. Such crucible may include graphite portions, for example graphite plates. In one aspect, an exemplary crucible may include two graphite plates, between which the metal part may be placed. In some embodiments, silicon carbide powder may be added to the crucible, for example to facilitate transport of the carbon species. In some embodiments, this process can take place inside a silicon carbide crucible or in the presence of silicon carbide vapor or silicon carbide may be used in other components of the system. In some embodiments, ambient oxygen or ambient hydrogen may become involved in the conversion of the parts.

The metal parts in the crucible may then be heated (e.g., in the range of 2000° C.-2300° C.), thus ferrying carbon to the reactive metal surface. Such deposition of carbon may convert the metal surface to a metal carbide, either converting the metal part entirely to a metal carbide part, or creating a metal carbide layer on the part. In some embodiments, the metal carbide layer may be 0.5 mm thick. In other embodiments, the metal carbide layer may be 1 mm thick. In other embodiments, the metal carbide layer may be up to 2 mm thick.

Aspects of the present disclosure also relate to a process of creating a coating from functionalized tantalum particles. Such a coating could be used to create coatings with a similar reaction mechanism to parts made from any material. Such a coating may allow for coating and thickening a variety of materials (e.g., vitreous carbon) without prior purification steps, which may risk altering the material structure.

In one process in accordance with the present disclosure a part may have a metal layer (e.g., tantalum) applied to at least one surface, including being enveloped by a contiguous layer of metal. Such a part may be coated with a coating that includes metal particles and a binder that forms a matrix holding the particles together in a coating. In some embodiments, the metal may be tantalum. In some embodiments, the metal particles may be less than 10 microns in diameter. In some embodiments, the binder may be a thermally curable resin. In some embodiments, the metal particles may be functionalized with compounds that promote particle dispersion in the coating and may couple to the binder. In some embodiments, the coating is stable in air, forms a stable suspension, and can be used to dip-coat or paint parts. In some embodiments, solvent may be added to the coating, for example to tune the viscosity of the coating, tune the metal particle concentration, or tune the coating uniformity. In some embodiments, a compound that promotes sintering may be added to the coating mixture to promote sintering of the particles (e.g., at temperatures above 1000° C.). The thickness of the final coating may be able to be controlled, for example by varying the concentration of metal particles in the coating and by varying the deposition volume of the coating onto the surface or part.

Aspects of the present invention also relate to creating standalone parts which may be formed and sintered into a final ceramic shape. Processes in accordance with the present disclosure may be capable of creating coatings much thicker than existing processes, including on the order of hundreds of microns thick. Thicker layers of material may provide parts that are not only diffusion barriers, but enable such parts to be structural elements. Processes for creating standalone parts may in some aspects be similar to the processes of coating a surface or part with metal-impregnated resins, with such metal-impregnated resins being used as material for 3D printing, casting, or coating disposable substrates, or otherwise forming objects that become standalone ceramic parts upon heat treatment and carburization of the metal. For example, metal-impregnated resins may be coated on a host material that will be removed through sublimation, evaporation, or a chemical process, leaving the metal carbide structure as a self supported element. Such a self-supported element may be part of a PVT/CVT or CVD system. Parts made from such processes may be more porous than a solid metal.

Aspects of the present disclosure may be used to create coatings on any surface within a crystal growth reactor or within any component within a reactor. For example, embodiments of the present disclosure may be used to create a coating on one or more surfaces of a crucible, an interior wall of a reactor, insulation, source retention elements, baffles, or any other structure shown or described herein, including a crucible, vessel, container, or part thereof, including a seed holder, lid, spacer ring, rod, liner, washer, shaft or porous barrier. In some embodiments, the crucible, vessel, container, or part thereof may be designed for use in the manufacture of silicon carbide wafers or boules. Such coatings according to certain aspects the present disclosure can be continuous, discontinuous, or patterned. Such films or coatings can be single coatings or part of a multi-coating layer. Coatings according to certain aspects of the present disclosure may be applied to one or more elements within a crystal growth system, either in their entirety or having portions coated, either as a single coating or multiple coatings or a patterned coating, for example, to achieve desired sublimation if such elements act as a secondary source or to reduce sublimation if such elements are not intended to serve as a secondary source. Coatings according to aspects of the present disclosure may be applied to one or more elements within a crystal growth system as a controlled secondary source of SiC or carbon and/or to control the ratio of carbon and silicon in the vapor. Coatings according to aspects of the present disclosure may act as a catalytic surface to help reduce contaminants.

Graphite structures may be treated to reduce particle emission, as disclosed in U.S. Provisional Application Ser. No. 63/700,630, filed on Sep. 28, 2024, which is hereby incorporated by reference.

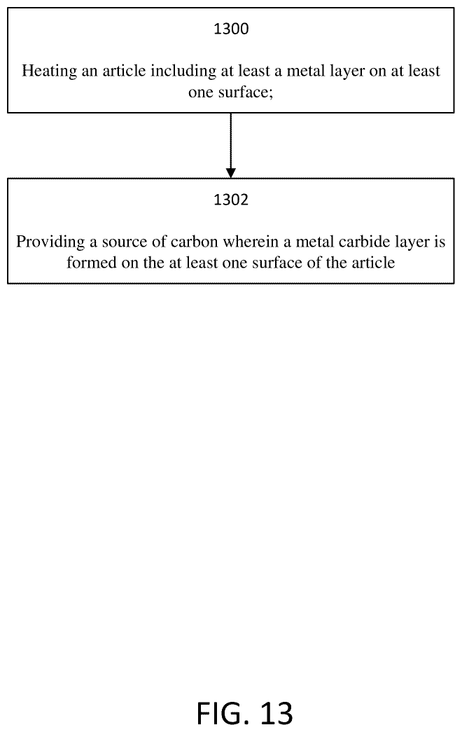

As shown in FIG. 13, certain aspects of this disclosure and their embodiments describe a method for creating a component for use in a crystal growth system, such method including: heating an article comprising at least a metal layer on at least one surface 1300, and providing a source of carbon wherein a metal carbide layer is formed on the at least one surface of the article 1302.

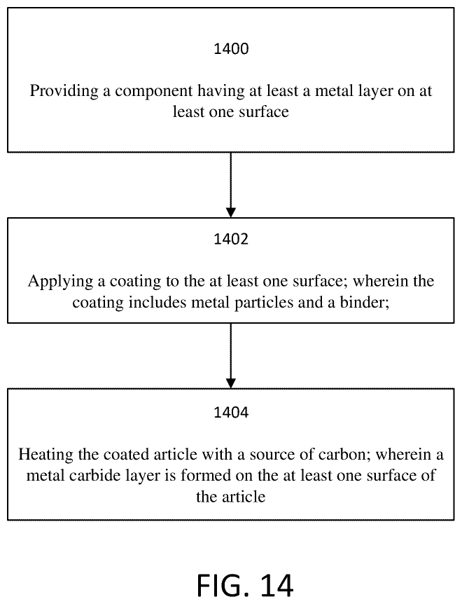

As shown in FIG. 14, certain aspects of this disclosure and their embodiments describe a method for creating an article for use in a crystal growth system, such method including providing an component having at least a metal layer on at least one surface 1400; applying a coating to the at least one surface wherein the coating is comprised of metal particles and a binder 1402; heating the coated article with a source of carbon wherein a metal carbide layer is formed on the at least one surface of the article 1404.

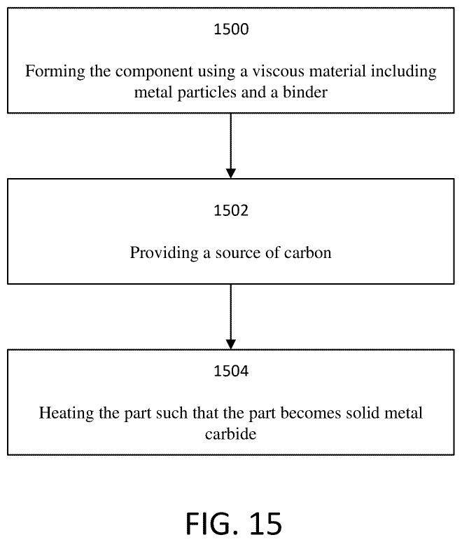

As shown in FIG. 15, certain aspects of this disclosure and their embodiments describe a method for creating a component, such method including forming the component using a viscous material comprising metal particles and a binder 1500, providing a source of carbon 1502, and heating the part such that the part becomes solid metal carbide 1504.

Further definitions and embodiments are discussed below.

In the above-description of various embodiments of present inventive concepts, it is to be understood that the terminology used herein is for the purpose of describing particular embodiments only and is not intended to be limiting of present inventive concepts. Unless otherwise defined, all terms (including technical and scientific terms) used herein have the same meaning as commonly understood by one of ordinary skill in the art to which present inventive concepts belong. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

As used herein, the singular forms “a”, “an” and “the” are intended to include the plural forms as well, unless the context clearly indicates otherwise. Well-known functions or constructions may not be described in detail for brevity and/or clarity. The term “and/or” (abbreviated “/”) includes any and all combinations of one or more of the associated listed items.

As used herein, the terms “comprise”, “comprising”, “comprises”, “include”, “including”, “includes”, “have”, “has”, “having”, or variants thereof are open-ended, and include one or more stated features, integers, elements, steps, components or functions but does not preclude the presence or addition of one or more other features, integers, elements, steps, components, functions or groups thereof. Furthermore, as used herein, the common abbreviation “e.g.”, which derives from the Latin phrase “exempli gratia,” may be used to introduce or specify a general example or examples of a previously mentioned item, and is not intended to be limiting of such item. The common abbreviation “i.e.”, which derives from the Latin phrase “id est,” may be used to specify a particular item from a more general recitation.

As used herein, “metal” may also include metalloids, including silicon, germanium, arsenic, antimony, tellurium, or polonium.

As used herein, the terms adhesive, bond, and coating are used interchangeably.

Example embodiments are described herein. Many variations and modifications can be made to the embodiments without substantially departing from the principles of the present inventive concepts. All such variations and modifications are intended to be included herein within the scope of present inventive concepts. Accordingly, the above disclosed subject matter is to be considered illustrative, and not restrictive, and the examples of embodiments are intended to cover all such modifications, enhancements, and other embodiments, which fall within the spirit and scope of present inventive concepts. Thus, to the maximum extent allowed by law, the scope of present inventive concepts are to be determined by the broadest permissible interpretation of the present disclosure including the examples of embodiments and their equivalents, and shall not be restricted or limited by the foregoing detailed description.

What is claimed is:

1. A method for creating a component for use in a crystal growth system, comprising:
heating an article comprising at least a metal layer on at least one surface;
providing a source of carbon
wherein a metal carbide layer is formed on the at least one surface of the article.

2. The method of claim 1, wherein the metal layer is made of a refractory metal.

3. The method of claim 1, wherein the metal layer is made of chromium, hafnium, iridium, molybdenum, niobium, osmium, rhenium, rhodium, ruthenium, tantalum, titanium, tungsten, vanadium, zirconium, or a mixture thereof.

4. The method of claim 1, wherein the article is made completely from a refractory metal.

5. The method of claim 1, wherein the article is made completely of chromium, hafnium, iridium, molybdenum, niobium, osmium, rhenium, rhodium, ruthenium, tantalum, titanium, tungsten, vanadium, zirconium, or a mixture thereof.

6. The method of claim 5, wherein the metal article is made of tantalum.

7. The method of claim 1, wherein the metal article is heated in a crucible.

8. The method of claim 7, wherein the crucible is a crystal growth crucible.

9. The method of claim 1, wherein the source of carbon is at least one of: a crucible, a powder, a gas, a coating on the at least one surface, or a portion of the article.

10. The method of claim 1, wherein the source of carbon is silicon carbide.

11. The method of claim 10, wherein the silicon carbide is a powder.

12. The method of claim 10, wherein the silicon carbide is at least a portion of the crucible.

13. The method of claim 1, wherein the crucible includes at least one graphite plate.

14. The method of claim 13, wherein the crucible includes two graphite plates.

15. The method of claim 14, further comprising pressing the article between the two graphite plates.

16. The method of claim 1, wherein the article is heated to at least 2000° C.

17. A component, comprising:
a metal component having a metal carbide layer on at least one surface;
wherein the metal carbide layer is formed by heating the metal article in a crucible with a source of carbon.

18. The component of claim 17, wherein the metal layer is made of a refractory metal.

19. The component of claim 17, wherein the metal layer is made of chromium, hafnium, iridium, molybdenum, niobium, osmium, rhenium, rhodium, ruthenium, tantalum, titanium, tungsten, vanadium, zirconium, or a mixture thereof.

20. The component of claim 17, wherein the article is made completely from a refractory metal.

21. The component of claim 17, wherein the article is made completely of chromium, hafnium, iridium, molybdenum, niobium, osmium, rhenium, rhodium, ruthenium, tantalum, titanium, tungsten, vanadium, zirconium, or a mixture thereof.

22. The component of claim 21, wherein the metal article is made of tantalum.

23. The component of claim 17, wherein the metal article is heated in a crucible.

24. The component of claim 23, wherein the crucible is a crystal growth crucible.

25. The component of claim 17, wherein the source of carbon is at least one of: a crucible, a powder, a gas, a coating on the at least one surface, or a portion of the article.

26. The component of claim 17, wherein the source of carbon is silicon carbide.

27. The component of claim 26, wherein the silicon carbide is a powder.

28. The component of claim 26, wherein the silicon carbide is at least a portion of the a crucible.

29. The component of claim 17, wherein the crucible includes at least one graphite plate.

30. The component of claim 29, wherein the crucible includes two graphite plates.

31. The component of claim 30, further comprising pressing the metal article between the two graphite plates.

32. The component of claim 17, wherein the metal article is heated to at least 2000° C.

33. A method for creating an article for use in a crystal growth system, comprising:
providing an component having at least a metal layer on at least one surface;
applying a coating to the at least one surface;
wherein the coating is comprised of metal particles and a binder;
heating the coated article with a source of carbon;
wherein a metal carbide layer is formed on the at least one surface of the article.

34. The method of claim 33, wherein the component is made of graphite.

35. The method of claim 33, wherein the component is made of metal.

36. The method of claim 33, wherein the component is made of a refractory metal.

37. The method of claim 33, wherein the component is made of chromium, hafnium, iridium, molybdenum, niobium, osmium, rhenium, rhodium, ruthenium, tantalum, titanium, tungsten, vanadium, zirconium, or a mixture thereof.

38. The method of claim 37, wherein the component is made of tantalum.

39. The method of claim 33, wherein the metal layer is made of a refractory metal.

40. The method of claim 33, wherein the metal layer is made of chromium, hafnium, iridium, molybdenum, niobium, osmium, rhenium, rhodium, ruthenium, tantalum, titanium, tungsten, vanadium, zirconium, or a mixture thereof.

41. The method of claim 40, wherein the metal layer is made of tantalum.

42. The method of claim 33, wherein the metal layer is contiguous.

43. The method of claim 33, wherein the metal layer is over the entire article.

44. The method of claim 33, wherein the metal particles are a refractory metal.

45. The method of claim 33, wherein the metal particles are chromium, hafnium, iridium, molybdenum, niobium, osmium, rhenium, rhodium, ruthenium, tantalum, titanium, tungsten, vanadium, zirconium, or a mixture thereof.

46. The method of claim 33, wherein the metal particles are tantalum.

47. The method of claim 33, wherein the metal particles are 10 microns or less in diameter.

48. The method of claim 33, wherein the binder is a thermally curable resin.

49. The method of claim 33, further comprising curing the coating.

50. The method of claim 49, further comprising thermally curing the coating.

51. The method of claim 50, further comprising thermally curing the coating at 150° C or greater.

52. The method of claim 33, wherein the coating further comprises at least one compound that promotes the dispersion of the metal particles.

53. The method of claim 33, wherein the coating further comprises at least one compound that promotes sintering.

54. The method of claim 33, wherein the coating is applied by dip coating.

55. The method of claim 33, wherein the coating further comprises a solvent.

56. The method of claim 33, wherein the metal article is heated in a crucible.

57. The method of claim 56, wherein the crucible is a crystal growth crucible.
